(19) United States
(12) Patent Application Publication
(10) Pub. No.: US 2025/0157749 A1
(43) Pub. Date: May 15, 2025

(54) POWER SWITCHING DEVICE AND ELECTRICAL DEVICE

(71) Applicant: OMRON Corporation, Kyoto-shi (JP)

(72) Inventors: Katsumi MATSUSHITA, Kyoto-shi (JP); Kenichi TABATA, Kyoto-shi (JP); Yoshiki FUKUTA, Kyoto-shi (JP)

(21) Appl. No.: 18/922,617

(22) Filed: Oct. 22, 2024

(30) Foreign Application Priority Data
Nov. 13, 2023 (JP) 2023-193116

(51) Int. Cl. H01H 9/02; H05K 5/02

(52) U.S. Cl. CPC H01H 9/02; H05K 5/0247

(57) ABSTRACT

A power switch including a communication unit communicably connected to an external device, a relay that opens and closes a power line supplying electric power from a power source to a load, a control unit that controls the relay based on information received from the external device via the communication unit, and an output connector connected with an output cable outputting the electric power input from the power source to the load. A connection surface of the output connector is provided so as to be inclined and face downward in a use state, in the connection surface, an insertion port connected with the output cable being opened.

### CROSS-REFERENCE TO RELATED APPLICATION

This application claims the benefit of priority to Japanese Patent Application Number 2023-193116 filed on Nov. 13, 2023. The entire contents of the above-identified application are hereby incorporated by reference.

### FIELD

The present invention relates to a power switch and an electric apparatus.

### BACKGROUND

Conventionally, in a cable connection device installed outdoors, when a cable is led out from the device in a lateral direction and dew condensation occurs on the cable, there is a concern that water droplets may move along the cable and enter the device, causing a short circuit.

Patent Document 1 discloses a control device housed in a charging station for an EV. However, since the control device is configured to be housed in a housing portion under the ground, Patent Document 1 relates to a technique for preventing submersion of an electric component due to heavy rain, and does not disclose a countermeasure against entry of water droplets due to dew condensation into a device via a cable.

### CITATION LIST

### Patent Literature

Patent Document 1: JP 2023-46536 A

### SUMMARY OF INVENTION

### Technical Problem

The present invention has been made in view of the above-described problems, and an object of the present invention is to provide a technique for preventing entry of water droplets due to dew condensation.

### Solution to Problem

The present invention for solving the above-described problems provides a power switch including: a communication unit communicably connected to an external device; a relay that opens and closes a power line supplying electric power from a power source to a load; a control unit that controls the relay based on information received from the external device via the communication unit; and an output connector connected with an output cable outputting the electric power input from the power source to the load, wherein the output connector includes a connection surface provided so as to be inclined and face downward in a use state, in the connection surface, an insertion port connected with the output cable being opened.

According to this configuration, when water droplets adhere to the output cable due to dew condensation, since the output cable is led out downward from the insertion port of the connection surface of the output connector, the water droplets adhering to the output cable move to the side opposite to the connection surface of the output connector, and the water droplets can be prevented from entering the power switch from the output connector along the output cable.

In the present invention, a housing that accommodates the communication unit, the relay, the control unit, and the output connector may be further included, and the housing may include an inclined surface portion provided so as to be continuous with a lower end portion of the connection surface exposed from the housing and so as to be inclined and face upward in the use state.

According to this configuration, since the inclined surface portion in the use state is provided so as to be continuous with the lower end portion of the connection surface exposed from the housing and so as to be inclined and face upward, water droplets adhering to the connection surface fall to the lower end portion along the connection surface and further fall downward along the inclined surface portion, so that it is possible to prevent the water droplets from entering the power switch from the connection surface of the output connector.

In the present invention, a first opening and a second opening may be further included, the first opening being provided at a surface of the housing extending in a vertical direction in the use state, the second opening being provided so as to be inclined and face downward at a position set back inside the housing in the use state, through the second opening, the connection surface being exposed. Further, the inclined surface portion may be formed so as to be continuous from a lower edge portion of the second opening to a lower edge portion of the first opening.

According to this configuration, the connection surface and the inclined surface portion of the output connector can be formed without increasing the volume of the housing.

In the present invention, the connection surface and/or the inclined surface portion may constitute a guide portion that guides the falling of water droplets.

According to this configuration, it is possible to cause water droplets adhering due to dew condensation to fall along one or both of the connection surface of the output connector and the inclined surface portion, and thus it is possible to prevent water droplets from entering the power switch.

In the present invention, an input connector connected with an input cable inputting the electric power from the power source may be further included, and a second insertion port connected with the input cable may be provided so as to open downward in the use state.

According to this configuration, since the input cable is connected to the second insertion port that opens downward from below in the use state, it is possible to prevent water droplets due to dew condensation from entering the power switch via the input connector.

Further, the present invention provides an electric apparatus including: a communication unit communicably connected to an external device; an output connector connected with an output line; a relay that opens and closes a line connected to the output connector; and a control unit that controls the relay based on information received from the external device via the communication unit, wherein the output connector includes a connection surface provided so as to be inclined and face downward in a use state, in the connection surface, an insertion port connected with the output line being opened.

According to this configuration, when water droplets adhere to the output line due to dew condensation, since the output line is led out downward from the insertion port of the connection surface of the output connector, the water droplets adhering to the output line move to the side opposite to the connection surface of the output connector, and the water droplets can be prevented from entering the electric apparatus from the output connector along the output line.

### Advantageous Effects

According to the present invention, it is possible to prevent the entry of water droplets due to dew condensation.

### BRIEF DESCRIPTION OF DRAWINGS

FIG. 1 is a diagram schematically illustrating an overall configuration of a charging system according to a first embodiment of the present invention.

FIG. 2 is an external perspective view of a power switching module according to the first embodiment of the present invention.

FIG. 3 is an exploded perspective view of the power switching module according to the first embodiment of the present invention.

FIG. 4 is a schematic cross-sectional view of the power switching module according to the first embodiment of the present invention.

FIG. 5 is a cross-sectional view illustrating a use state of an output connector of the power switching module according to the first embodiment of the present invention.

FIG. 6 is a partial cross-sectional view illustrating a use state of the periphery of the output connector of the power switching module according to the first embodiment of the present invention.

FIG. 7 is another schematic cross-sectional view of the power switching module according to the first embodiment of the present invention.

### DETAILED DESCRIPTION

### Application Example

Hereinafter, an application example of the present invention will be described with reference to the drawings.

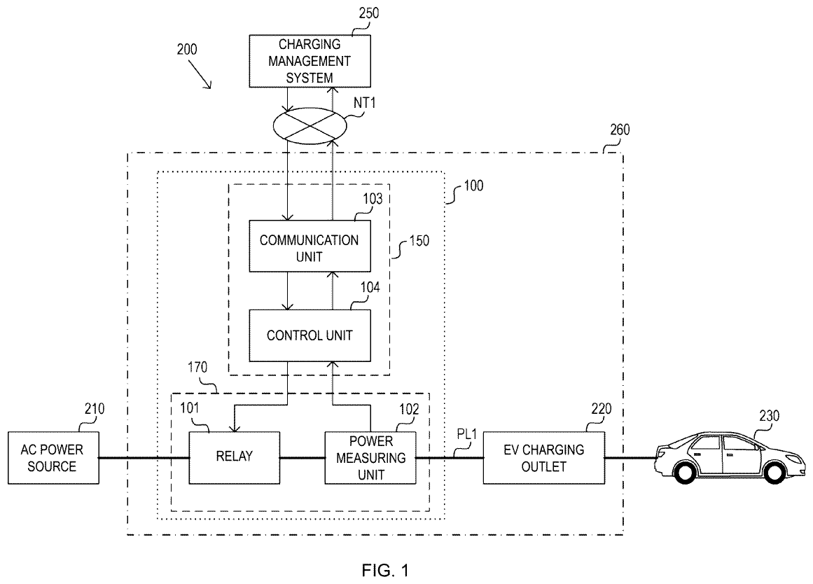

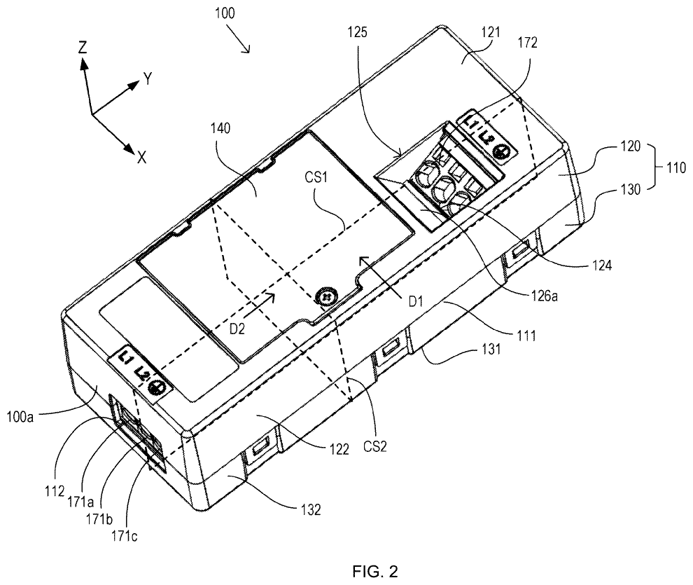

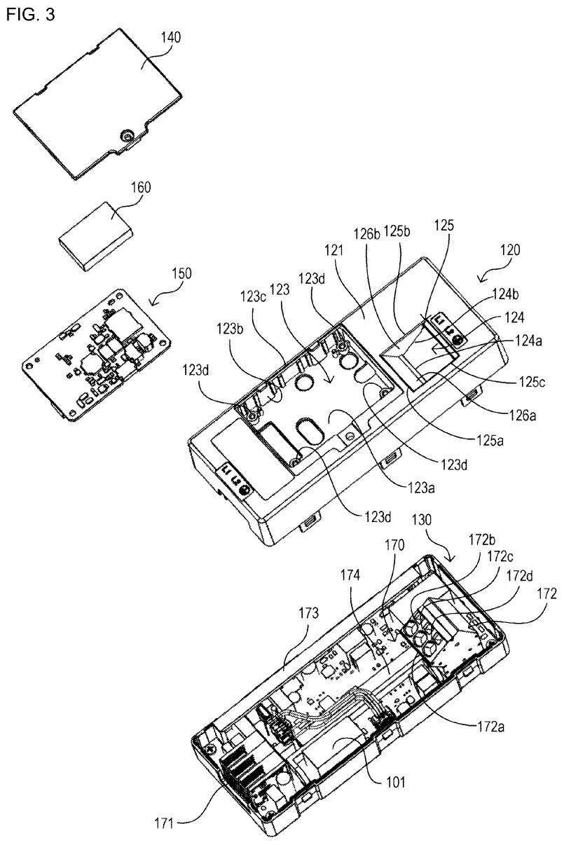

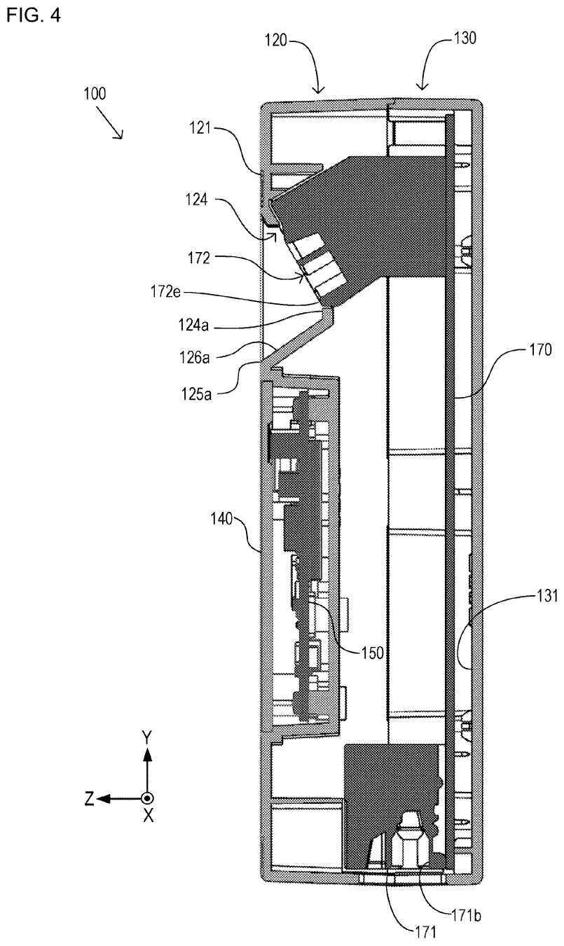

FIG. 2 is a schematic perspective view of a power switching module 100 used in a charging system 200 illustrated in FIG. 1. FIG. 3 is an exploded perspective view of the power switching module 100, and FIG. 4 is a schematic cross-sectional view of the power switching module 100.

The charging system 200 includes an EV charging outlet 220, a power switching module 100 that opens and closes a power line PL1 for charging a storage battery of an electric vehicle (EV) 230 connected via the EV charging outlet 220 with electric power supplied from an AC power source 210, and a charging management system 250 connected to the power switching module 100 via a network NT1.

The power switching module 100 includes a relay 101 that opens and closes the power line PL1, a power measuring unit 102 that measures the electric power supplied to the EV 230 through the power line PL1, a communication unit 103 that transmits and receives information between the power switching module 100 and an external device by a predetermined communication method, and a control unit 104 that integrally controls the relay 101, the power measuring unit 102, and the communication unit 103.

The power switching module 100 is accommodated as a module in a housing of a pole or a box which is a charging facility 260 provided with the EV charging outlet 220.

An opening 124 having a substantially square shape is formed near an upper end in the longitudinal direction of a front surface portion 121 of a front side case 120, and an output connector 172 to be described below is exposed through the opening 124. The opening 124 is provided so as to be inclined and face downward at a position set back from the front surface portion 121 toward the inner side of a housing 110, that is, toward a back surface portion 131. A guide portion 126a having a substantially rectangular plate shape is provided so as to extend from a lower end edge 125a of an outer opening 125 to a lower end edge 124a of the opening 124, the outer opening 125 having a substantially square shape and being provided near the upper end in the longitudinal direction of the front surface portion 121 of the front side case 120.

The guide portion 126a is inclined so as to face upward. An end edge of the guide portion 126a on the opening 124 side is bent in a Y direction. A sidewall 126b having a substantially triangular plate shape is provided so as to extend from a left end edge 125b of the outer opening 125 to a left end edge 124b of the opening 124. Similarly, a sidewall having a substantially triangular shape is provided so as to extend from a right (X direction) end edge 125c of the outer opening 125 to a right end edge of the opening 124.

A connection surface 172a of the output connector 172 exposed through the opening 124 of the front side case 120 is inclined downward (in the − (minus) Y direction) from the front side (Z direction) to correspond to the opening 124. Three insertion ports 172b to 172d for connecting an output cable that connects the power switching module 100 and the EV charging outlet 220 are provided at the connection surface 172a of the output connector 172.

On the lower side (−Y direction) of the power switching module 100, an opening 112 is provided across a sidewall portion 122 of the front side case 120 and a sidewall portion 132 of a back side case 130, and an input connector 171 for connecting an input cable that connects be the AC power source 210 and the power switching module 100 is exposed through the opening 112. In the input connector 171, insertion ports 171a to 171c connected with the input cable are provided so as to open downward (−Y direction). Water droplets adhering to the sidewall portion 122 on the lower side (−Y direction) of the front side case 120, the sidewall portion 132 on the lower side (−Y direction) of the back side case 130, and the input cable due to dew condensation fall downward, and thus can be prevented from entering the power switching module 100.

FIG. 4 illustrates a schematic cross-sectional view of the power switching module 100. In FIG. 4, members are omitted as appropriate for convenience of description. The cross-section illustrated in FIG. 4 is a cross-section parallel to the YZ plane of the portion indicated by a broken line CS1 in FIG. 2, as viewed from the direction of an arrow D1. FIG. 4 illustrates a posture in a normal use state accommodated in the charging facility 260, in which the Y direction is an upward direction. At this time, the EV charging outlet 220 is positioned on the front side of a post or a box which is the charging facility 260, that is, in the Z direction of the power switching module 100 illustrated in FIG. 4.

As described above, the opening 124 of the housing 110 and the connection surface 172a of the output connector 172 are provided so as to be inclined and face downward.

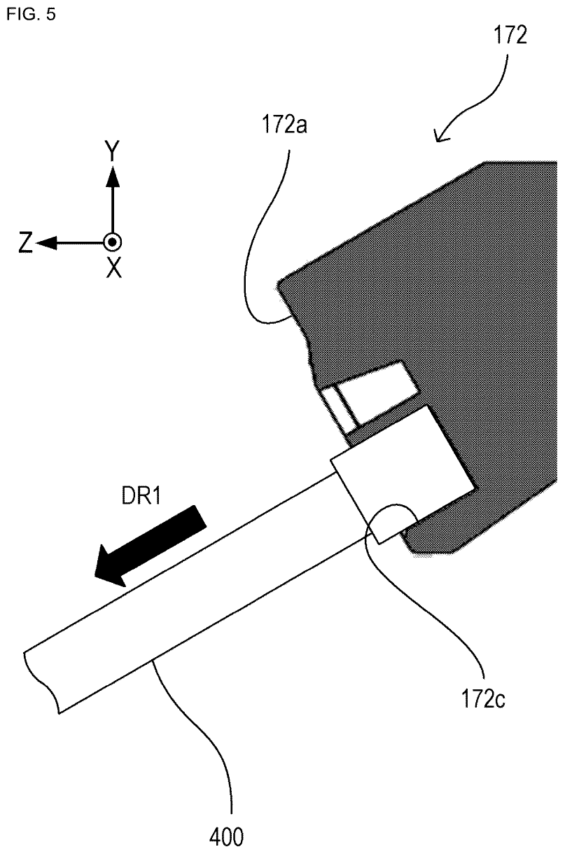

FIG. 5 is a diagram schematically illustrating only the output connector 172 in the cross-sectional view illustrated in FIG. 4. FIG. 5 illustrates the relationship between the insertion port 172c of the output connector 172 and an output cable 400 connected to the insertion port 172c (the same applies to the insertion ports 172b and 172d). The power switching module 100 is installed in the housing of the charging facility 260 in the posture illustrated in FIG. 4. One end of the output cable 400 is connected to the insertion port 172c of the output connector 172, and the other end is connected to the EV charging outlet 220. Since the connection surface 172a of the output connector 172 is inclined so as to face downward, the insertion port 172c is provided so as to face upward from the connection surface 172a into the power switching module 100. Thus, the output cable 400 connected to the output connector 172 is led out from the output connector 172 side toward the front side so as to at least first hang downward. Regardless of the relative positional relationship between the power switching module 100 (the output connector 172) and the EV charging outlet 220, when dew condensation occurs on the surface of the output cable 400, water droplets move downward on the output cable 400 as indicated by an arrow DR1, and thus can be prevented from entering the power switching module 100.

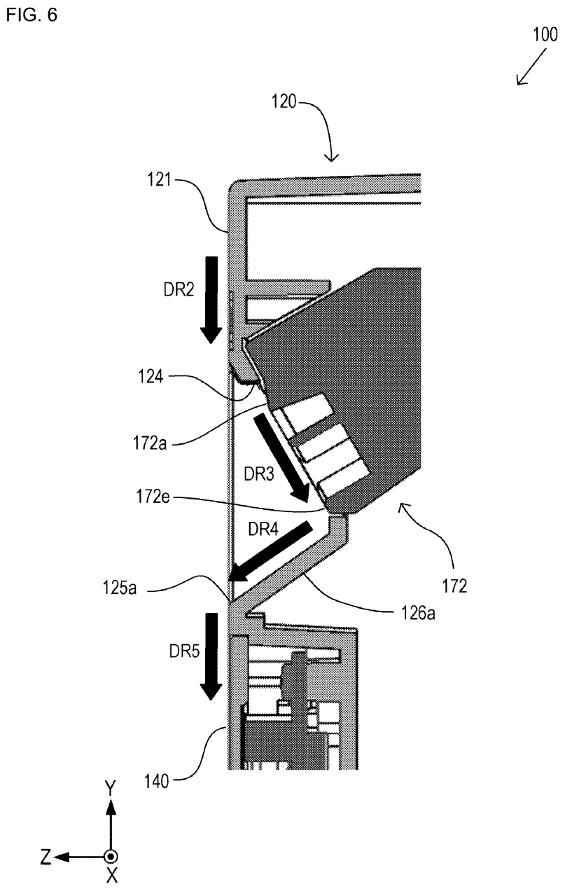

FIG. 6 is a diagram schematically illustrating the periphery of the output connector 172 in the cross-sectional view illustrated in FIG. 4. As described with reference to FIG. 4, the power switching module 100 is disposed along the vertical direction (Y-axis direction).

Water droplets adhering to the front surface portion 121 of the front side case 120 fall downward along the front surface portion 121 as indicated by an arrow DR2, move beyond the opening 124 side or the outer opening 125, and fall downward along the front surface portion 121 or an opening cover 140 as indicated by an arrow DR5. The water droplets having moved to the opening 124 side fall downward along the connection surface 172a of the output connector 172 exposed through the opening 124 as indicated by an arrow DR3, or fall along the output cable 400 as indicated by the arrow DR1 as illustrated in FIG. 5. The water droplets having fallen downward along the exposed connection surface 172a move beyond the opening 124 and fall downward along the guide portion 126a. The water droplets having reached the lower end of the guide portion 126a fall from the lower end edge 125a of the outer opening 125 along the front surface portion 121 or the opening cover 140.

Since water droplets adhering to the surface of the front side case 120 due to dew condensation fall downward as described above, it is possible to prevent the water droplets from entering the power switching module 100.

### First Embodiment

Hereinafter, a charging system 200 including a power switching module 100 according to a first embodiment of the present invention will be described in more detail with reference to the drawings. However, the configuration of the apparatus and the system described in this embodiment should be changed as appropriate in accordance with various conditions. That is, the scope of the present invention is not intended to be limited to the embodiment described blow.

The charging system 200 includes an EV charging outlet 220, a power switching module 100 that opens and closes a power line PL1 for charging a storage battery of an electric vehicle (EV) 230 connected via the EV charging outlet 220 with electric power supplied from an AC power source 210, and a charging management system 250 connected to the power switching module 100 via a network NT1. Here, the AC power source 210 and the EV 230 correspond to the power source and the load of the present invention, respectively. The power line PL1 corresponds to the power line and the line of the present invention. The power switching module 100 corresponds to the power switch and the electric apparatus of the present invention, and the charging management system 250 corresponds to the external device of the present invention.

The power switching module 100 mainly includes a relay 101, a power measuring unit 102, a communication unit 103, and a control unit 104. The relay 101 opens and closes the power line PL1 connecting the AC power source 210 and the EV charging outlet 220. The power measuring unit 102 measures electric power supplied to the EV 230 through the power line PL1.

The communication unit 103 is an interface that transmits and receives information between the power switching module 100 and an external device by a predetermined communication method. The control unit 104 integrally controls the relay 101, the power measuring unit 102, and the communication unit 103. Here, the relay 101, the communication unit 103, and the control unit 104 correspond to the relay, the communication unit, and the control unit of the present invention, respectively.

The control unit 104 includes a processor such as an MPU and a memory.

An operation example of the above-described charging system 200 will be described below.

The charging management system 250 is, for example, a computer device such as a plurality of servers disposed on a cloud.

The charging management system 250 monitors and controls the power switching module 100 connected via the network NT1.

For example, the power switching module 100 is accommodated as a module in the housing of a pole or a box which is a charging facility 260 provided with the EV charging outlet 220. The relay 101 and the power measuring unit 102 are disposed on the power line PL1 that connects the AC power source 210 and the EV charging outlet 220 and supplies AC electric power supplied from the AC power source 210 to the EV 230 via the EV charging outlet 220. The relay 101 opens and closes the power line PL1 in accordance with an instruction from the control unit 104 to charge the storage battery of the EV 230. The power measuring unit 102 measures electric power or an amount of the electric power supplied from the AC power source 210 to the EV 230 via the EV charging outlet 220. The charging management system 250 monitors and controls the operation of the power switching module 100 based on necessary information transmitted from the communication unit 103.

FIG. 2 is a perspective view illustrating an outer shape of the power switching module 100, and FIG. 3 is an exploded perspective view of the power switching module 100. Note that in FIG. 3, members are omitted as appropriate for convenience of description.

The power switching module 100 is disposed in the housing of a pole or a box which is the charging facility 260 such that the Z direction illustrated in FIG. 2 is the front side (the −Z direction is the back side), the Y direction is the upper side (the −Y direction is the lower side), and the X direction is the right side when facing the front side (the −X direction is the left side when facing the front side) in the use state. At this time, the front side is a side on which the EV charging outlet 220 is disposed in the charging facility 260. In the following description, front (foreside), back, upper, lower, left, and right are based on a state viewed from the front side in the use state.

The power switching module 100 generally includes a housing 110 including a front side case 120 and a back side case 130, an opening cover 140, an IoT substrate 150, a thermal conductive sheet 160, and a power substrate 170. The housing 110 having a substantially rectangular parallelepiped shape with a hollow interior is divided into the front side case 120 on the front side and the back side case 130 on the back side along a dividing plane 111 parallel to a front surface portion 121 and a back surface portion 131. The front side case 120 and the back side case 130 are coupled to each other by appropriate coupling means. The front side case 120 has a substantially rectangular cylindrical shape with a bottom and includes a sidewall portion 122 rising from the circumference of the front surface portion 121 having a substantially rectangular shape parallel to the XY plane in a direction (−Z direction) orthogonal to the front surface portion 121. Similarly, the back side case 130 has a substantially rectangular cylindrical shape with a bottom and includes a sidewall portion 132 rising from the circumference of the back surface portion 131 having a substantially rectangular shape parallel to the XY plane in a direction (Z direction) orthogonal to the back surface portion 131. With the divided structure in which the housing 110 is divided into the front side case 120 and the back side case 130, the housing 110 of the power switching module 100 can be formed with a simple configuration. Here, the housing 110 corresponds to the housing of the present invention. The front surface portion 121 constitutes a front surface of the present invention. The front surface of the present invention may include the sidewall portion 122 of the housing 110. In that case, the front side case 120 and the back side case 130 may also be referred to as a second housing portion and a first housing portion of the housing 110, respectively. The opening cover 140 and the thermal conductive sheet 160 may also be referred to as a lid portion and a heat conductive member, respectively. The IoT substrate 150 and the power substrate 170 may also be referred to as a second substrate and a first substrate, respectively.

Near the lower end in the longitudinal direction (Y-axis direction) of the front surface portion 121 of the front side case 120, a recessed portion 123 having a substantially rectangular parallelepiped shape that is recessed from the front side to the back side is formed. The recessed portion 123 has a bottom portion 123a parallel to the front surface portion 121, and a sidewall portion 123b which is rising from the circumference of the bottom portion 123a perpendicularly to the bottom portion 123a and is connected to the front surface portion 121, whereby an opening 123c opened to the outside (front side) is formed. The opening 123c of the recessed portion 123 provided in the front side case 120 is covered with the opening cover 140, which is a substantially rectangular plate-like member, in an openable and closable manner.

An opening 124 having a substantially square shape is formed near the upper end in the longitudinal direction of the front surface portion 121 of the front side case 120, and an output connector 172 to be described below is exposed through the opening 124 toward the front side. The opening 124 is provided so as to be inclined downward (−Y direction) at a position set back from the front surface portion 121 parallel to the XY plane toward the inner side of the housing 110, that is, toward the back surface portion 131 (−Z direction). A guide portion 126a having a substantially rectangular plate shape is provided so as to extend from a lower (−Y direction) end edge 125a of an outer opening 125 to a lower (−Y direction) end edge 124a of the opening 124, the outer opening 125 having a substantially square shape and being provided near the upper end in the longitudinal direction of the front surface portion 121 of the front side case 120. The guide portion 126a is inclined from the upper side (Y direction) to the front side (Z direction). An end edge of the guide portion 126a on the opening 124 side is bent in the Y direction. A sidewall 126b having a substantially triangular plate shape is provided so as to extend from a left (−X direction) end edge 125b of the outer opening 125 to a left (−X direction) end edge 124b of the opening 124. Similarly, a sidewall having a substantially triangular shape is provided so as to extend from a right (X direction) end edge 125c of the outer opening 125 to a right end edge of the opening 124. Here, the output connector 172 corresponds to the output connector of the present invention. The outer opening 125 corresponds to the first opening of the present invention, and the opening 124 corresponds to the second opening of the present invention. The lower end edge 125a of the outer opening 125 corresponds to the lower edge portion of the first opening of the present invention, and the lower end edge 124a of the opening 124 corresponds to the lower edge portion of the second opening of the present invention. The guide portion 126a corresponds to the inclined surface portion and the guide portion of the present invention.

A connection surface 172a of the output connector 172 exposed through the opening 124 of the front side case 120 is inclined downward (in the −Y direction) from the front side (Z direction) to correspond to the opening 124. Three insertion ports 172b to 172d for connecting an output cable 400 or the like (see FIG. 5) that connects the power switching module 100 and the EV charging outlet 220 are provided at the connection surface 172a of the output connector 172. Here, the connection surface 172a corresponds to the connection surface of the present invention. The insertion ports 172b to 172d correspond to the insertion port of the present invention. The output cable 400 corresponds to the output cable and the output line of the present invention.

On the lower side (−Y direction) of the power switching module 100, an opening 112 is provided across the sidewall portion 122 of the front side case 120 and the sidewall portion 132 of the back side case 130, and an input connector 171 for connecting an input cable that connects the AC power source 210 and the power switching module 100 is exposed through the opening 112. In the input connector 171, insertion ports 171a to 171c connected with the input cable are provided so as to open downward (−Y direction). Water droplets adhering to the sidewall portion 122 on the lower side (−Y direction) of the front side case 120, the sidewall portion 132 on the lower side (−Y direction) of the back side case 130, and the input cable due to dew condensation fall downward, and thus can be prevented from entering the power switching module 100. Here, the input connector 171 corresponds to the input connector of the present invention, and the insertion ports 171a to 171c correspond to the second insertion port of the present invention.

In FIG. 4 illustrating a schematic cross-sectional view of the power switching module 100, members are omitted as appropriate for convenience of description. The cross-section illustrated in FIG. 4 is a cross-section parallel to the YZ plane of the portion indicated by the broken line CS1 in FIG. 2, as viewed from the direction of the arrow D1. FIG. 4 illustrates a posture in a normal use state accommodated in the charging facility 260, in which the Y direction is an upward direction. At this time, the EV charging outlet 220 is positioned on the front side of a post or a box which is the charging facility 260, that is, in the Z direction of the power switching module 100 illustrated in FIG. 4.

As described above, the opening 124 of the housing 110 and the connection surface 172a of the output connector 172 are provided so as to be inclined and face downward (−Y direction).

FIG. 5 is a diagram schematically illustrating only the output connector 172 in the cross-sectional view illustrated in FIG. 4. FIG. 5 illustrates the relationship between the insertion port 172c of the output connector 172 and the output cable 400 connected to the insertion port 172c (the same applies to the insertion ports 172b and 172d). The power switching module 100 is installed in the housing of the charging facility 260 in the posture illustrated in FIG. 4. It is desirable that the housing of the charging facility 260 has a waterproof structure. In general, the EV charging outlet 220 is disposed so as to face downward at the front surface of the charging facility 260, and is configured such that a charging plug is inserted upward from below. One end of the output cable 400 is connected to the insertion port 172c of the output connector 172, and the other end is connected to the EV charging outlet 220. Since the connection surface 172a of the output connector 172 is inclined so as to face downward, the insertion port 172c is provided so as to face upward from the connection surface 172a into the power switching module 100. Thus, the output cable 400 connected to the output connector 172 is led out from the output connector 172 side toward the front side (Z direction) so as to at least first hang downward (−Y direction). The relative positional relationship between the power switching module 100 (output connector 172) and the EV charging outlet 220 in the vertical direction (Y-axis direction) may vary depending on the configuration of the charging facility 260. However, since the output connector 172 and the output cable 400 has the above-described relationship, even when dew condensation occurs on the surface of the output cable 400, water droplets move downward (−Y direction) on the output cable 400 as indicated by the arrow DR1, and can be prevented from entering the power switching module 100.

FIG. 6 is a diagram schematically illustrating the periphery of the output connector 172 in the cross-sectional view illustrated in FIG. 4. As described with reference to FIG. 4, the power switching module 100 is disposed along the vertical direction (Y-axis direction).

As illustrated in FIG. 6, the connection surface 172a is exposed through the opening 124 provided at a position set back from the outer opening 125 provided in the front surface portion 121 of the front side case 120 toward the inside of the housing 110. The guide portion 126a extending from the lower end edge 124a of the opening 124 to the lower end edge 125a of the outer opening 125 is provided so as to be continuous with a lower end portion 172e of the connection surface 172a.

Water droplets adhering to the front surface portion 121 of the front side case 120 fall downward along the front surface portion 121 as indicated by an arrow DR2, move beyond the opening 124 side or the outer opening 125, and fall downward along the front surface portion 121 or an opening cover 140 as indicated by an arrow DR5. The water droplets having moved to the opening 124 side fall downward along the connection surface 172a of the output connector 172 exposed through the opening 124 as indicated by an arrow DR3, or fall along the output cable 400 as indicated by the arrow DR1 as illustrated in FIG. 5. The water droplets having fallen downward along the exposed connection surface 172a move beyond the opening 124 and fall downward along the guide portion 126a. The water droplets having reached the lower end of the guide portion 126a fall from the lower end edge 125a of the outer opening 125 along the front surface portion 121 or the opening cover 140.

Similarly, as indicated by the arrows DR3, DR4, and DR5, water droplets adhering to the connection surface 172a of the output connector 172 fall along the connection surface 172a, the guide portion 126a, and the front surface portion 121 or the opening cover 140. Similarly, as indicated by the arrows DR4 and DR5, water droplets adhering to the guide portion 126a fall along the guide portion 126a and the front surface portion 121 or the opening cover 140. Similarly, water droplets adhering to the front surface portion 121 or the opening cover 140 below the outer opening 125 fall along the front surface portion 121 or the opening cover 140 as indicated by the arrow DR5.

Since water droplets adhering to the surface of the front side case 120 due to dew condensation fall downward as described above, it is possible to prevent the water droplets from entering the power switching module 100.

In the power switching module 100, a circuit substrate is divided into the IoT substrate 150 and the power substrate 170 as described above. Respective electronic components functioning as the communication unit 103 and the control unit 104 are mounted on the IoT substrate 150. The relay 101 and the power measuring unit 102 are mounted on the power substrate 170, forming a part of the power line PL1. In addition, bus bars 173 and 174 are connected to the power substrate 170 as a part of the power line PL1 to secure a capacity for electric power supplied from the AC power source 210 to the EV 230 via the power switching module 100.

The thermal conductive sheet 160 is a sheet made of a thermally conductive member such as silicon, and is disposed between the IoT substrate 150 and the opening cover 140.

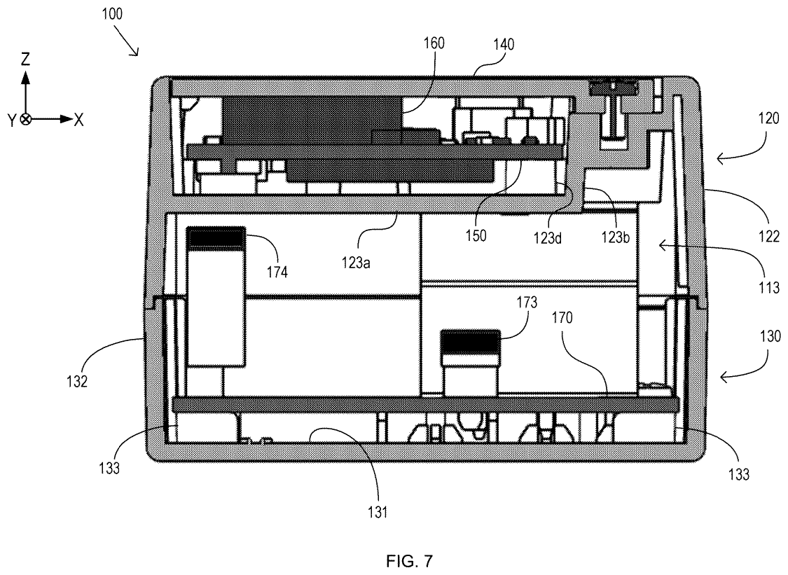

FIG. 7 illustrates a schematic cross-sectional view of the power switching module 100. In FIG. 7, members are omitted as appropriate for convenience of description. The cross-section illustrated in FIG. 7 is a cross-section parallel to the XZ plane of the portion indicated by a broken line CS2 in FIG. 2 as viewed from the direction of an arrow D2.

The IoT substrate 150 is disposed in the recessed portion 123 provided on the front surface portion 121 side of the front side case 120, and is connected to the power substrate 170 disposed in the back side case 130. The IoT substrate 150 is retained at a position separated from the bottom portion 123a by retaining portions 123d having a cylindrical shape and being disposed at four corners of the bottom portion 123a of the recessed portion 123.
The thermal conductive sheet 160 disposed between the IoT substrate 150 and the opening cover 140 is slightly crushed between the opening cover 140 and the IoT substrate 150 in a state where the opening cover 140 is closed to come into close contact with the IoT substrate 150 and the opening cover 140, thereby performing a function of transferring heat generated in the IoT substrate 150 to the opening cover 140 and radiating the heat from the opening cover 140.

The power substrate 170 is retained so as to be separated from the back surface portion 131 by a retaining portion 133 disposed on the back surface portion 131 of the back side case 130. Each of the bus bars 173 and 174 extends from the power substrate 170 toward the front side, that is, the front side case 120 side, and is disposed along the longitudinal direction (Y-axis direction) of the back side case 130. As illustrated in FIG. 4, the power substrate 170 including the bus bars 173 and 174 is disposed in an internal space 113 defined by the front side case 120 and the back side case 130. Heat generated from the power substrate 170 is released to the periphery of the power switching module 100 via the bottom portion 123a and the sidewall portion 123b of the recessed portion 123, the sidewall portion 122 of the front side case 120, and the back side case 130 surrounding the internal space 113. Here, the internal space 113 may be referred to as a hollow interior of the housing 110, the bottom portion 123a and the sidewall portion 123b of the recessed portion 123, the sidewall portion 122 of the front side case 120, and the back side case 130 may be referred to as a first chamber of the housing 110, and the recessed portion 123 may be referred to as a second chamber of the housing 110. In that case, the bottom portion 123a and the sidewall portion 123b of the recessed portion 123 can also be referred to as partition walls that separate the first chamber and the second chamber from each other.

As described above, the heat generated from the IoT substrate 150 is released to the front surface portion 121 side of the power switching module 100 via the thermal conductive sheet 160 and the opening cover 140. Since the IoT substrate 150 is disposed in the recessed portion 123 of the front side case 120, the IoT substrate 150 is separated from the internal space 113 in which the power substrate 170 is disposed by the bottom portion 123a of the recessed portion 123, and is retained by the retaining portions 123d so as to be also separated from the bottom portion 123a. Accordingly, the influence of heat generation in the power substrate 170 on the MPU or the like mounted on the IoT substrate 150 is reduced, and the temperature rise of the MPU or the like is suppressed. Thus, the communication unit 103 and the control unit 104 can be operated within an appropriate temperature range, and the reliability of the operation of the power switching module 100 can be ensured. In addition, by configuring the power switching module 100 as described above, the entire apparatus can be made compact by suppressing the volume, and the power switching module 100 can be installed in a post or box charging facility in which the volume of an internal space is limited.

### Modification

An electric apparatus to which the above-described configuration of the output connector capable of preventing entry of water droplets can be applied is not limited to the power switching module 100 constituting the charging system 200 for charging the storage battery of the EV 230 described as the first embodiment. For example, the configuration can be applied to a power conditioner and a control device used for controlling a social infrastructure, but is not limited thereto.

In an electric apparatus to which the configuration of the output connector can be applied, a line opened and closed by a relay is not limited to a power line such as the power line PL1 described above, but may be a signal line, and may be a line through which a current flows in order to output electric power, a signal, or the like via an output line connected to an output connector. In such an electric apparatus, similarly to the output connector 172 according to the first embodiment, a connection surface of the output connector exposed through an opening on the front surface side of a housing is inclined downward (in the −Y direction) from the front side (Z direction) so as to correspond to the opening, and a guide portion extending from the lower end edge of the opening to the lower end edge of another opening of the housing is provided so as to be continuous with the lower end portion of the connection surface, whereby water droplets adhering to the output line and the housing can be prevented from entering the inside.

Note that, in order to enable the comparison between the constituent features of the present invention and the configurations of the embodiment, the constituent features of the present invention will be described below with reference signs in the drawings.

### Supplementary Note 1

A power switch (100) including:
a communication unit (103) communicably connected to an external device (250);
a relay (101) that opens and closes a power line (PL1) supplying electric power from a power source (210) to a load (230);
a control unit (104) that controls the relay (101) based on information received from the external device (250) via the communication unit (103); and
an output connector (172) connected with an output cable (400) outputting the electric power input from the power source (210) to the load (230),
wherein the output connector (172) includes a connection surface (172a) provided so as to be inclined and face downward in a use state, in the connection surface (172a), an insertion port (172b to 172d) connected with the output cable (400) being opened.

### Supplementary Note 2

The power switch (100) according to Supplementary Note 1, further including a housing (110) that accommodates the communication unit (103), the relay (101), the control unit (104), and the output connector (172), wherein the housing (110) includes an inclined surface portion (126a) provided so as to be continuous with a lower end portion (172e) of the connection surface (172a) exposed from the housing (110) and so as to be inclined and face upward in the use state.

### Supplementary Note 3

The power switch (100) according to Supplementary Note 2, further including: a first opening (125) provided at a surface of the housing (110) extending in a vertical direction in the use state; and
a second opening (124) provided so as to be inclined and face downward at a position set back inside the housing (110) in the use state, through the second opening (124), the connection surface (172a) being exposed,
wherein the inclined surface portion (126a) is formed so as to be continuous from a lower edge portion (124a) of the second opening (124) to a lower edge portion (125a) of the first opening (125).

### Supplementary Note 4

The power switch (100) according to Supplementary Note 2 or 3, wherein the connection surface (172a) and/or the inclined surface portion (126a) constitute/constitutes a guide portion (172a, 126a) that guides falling of water droplets.

### Supplementary Note 5

The power switch (100) according to any one of Supplementary Notes 1 to 4, further including an input connector (171) connected with an input cable inputting the electric power from the power source (210), wherein a second insertion port (171a to 171c) connected with the input cable is provided so as to open downward in the use state.

### Supplementary Note 6

An electric apparatus (100) including:
a communication unit (103) communicably connected to an external device (250);
an output connector (172) connected with an output line (400);
a relay (101) that opens and closes a line (PL1) connected to the output connector (172); and
a control unit (104) that controls the relay (101) based on information received from the external device (250) via the communication unit (103), the output connector (172) including a connection surface (172a) provided so as to be inclined and face downward in a use state, in the connection surface (172a), an insertion port (172b to 172d) connected with the output line (400) being opened.

1. A power switch comprising:
a communication unit communicably connected to an external device;
a relay configured to open and close a power line supplying electric power from a power source to a load;
a control unit configured to control the relay based on information received from the external device via the communication unit; and
an output connector connected with an output cable outputting the electric power input from the power source to the load,
wherein the output connector includes a connection surface provided so as to be inclined and face downward in a use state, in the connection surface, an insertion port connected with the output cable being opened.

2. The power switch according to claim 1, further comprising:
a housing configured to accommodate the communication unit, the relay, the control unit, and the output connector,
wherein the housing includes an inclined surface portion provided so as to be continuous with a lower end portion of the connection surface exposed from the housing and so as to be inclined and face upward in the use state.

3. The power switch according to claim 2, further comprising:
a first opening provided at a surface of the housing extending in a vertical direction in the use state; and
a second opening provided so as to be inclined and face downward at a position set back inside the housing in the use state, through the second opening, the connection surface being exposed,
wherein the inclined surface portion is formed so as to be continuous from a lower edge portion of the second opening to a lower edge portion of the first opening.

4. The power switch according to claim 2, wherein the connection surface and/or the inclined surface portion constitute/constitutes a guide portion configured to guide falling of water droplets.

5. The power switch according to claim 1, further comprising:
an input connector connected with an input cable inputting the electric power from the power source,
wherein a second insertion port connected with the input cable is provided so as to open downward in the use state.

6. An electric apparatus comprising:
a communication unit communicably connected to an external device;
an output connector connected with an output line;
a relay configured to open and close a line connected to the output connector; and
a control unit configured to control the relay based on information received from the external device via the communication unit,
the output connector including a connection surface provided so as to be inclined and face downward in a use state, in the connection surface, an insertion port connected with the output line being opened.
